(19) United States
(12) Patent Application Publication
(10) Pub. No.: US 2025/0172608 A1
(43) Pub. Date: May 29, 2025

(54) SYSTEMS AND METHODS FOR TESTING THERMAL CONDITIONING OF AN INTEGRATED CIRCUIT (IC)

(71) Applicant: SMART Modular Technologies, Inc., Newark, CA (US)

(72) Inventors: Reuben Chang, Poway, CA (US); Torry Steed, Poway, CA (US)

(21) Appl. No.: 18/520,843

(22) Filed: Nov. 28, 2023

(51) Int. Cl. G01R 31/28

(52) U.S. Cl. CPC G01R 31/2875

(57) ABSTRACT

Systems and methods for testing the thermal conditioning of an integrated circuit (IC) are disclosed. In one aspect, a device is used to apply heat to a chip, and more particularly to a memory element, while providing thermal isolation to a motherboard with which circuits in the chip may be operating. Testing sensors may monitor operation of the circuits in the chip while the heat is applied to the chip. Having a device that is easily coupled to the chip under test, readily applies heat without damaging other components on a motherboard and allows testing of the chip under test will save time and provide better test results so that chips may be certified for operation at such elevated temperatures and/or provide a better product to customers.

### BACKGROUND

### I. Field of the Disclosure

The technology of the disclosure relates generally to testing integrated circuits and, more particularly, to testing integrated circuits under temperature extremes.

### II. Background

Computing devices abound in modern society. This prevalence is driven by the increasing power of the processors used to perform the functions of the computing devices, along with myriad new applications that use this increased processing power. There is a perceived push to create ever more powerful processors that require ever larger memory blocks. Currently, the processors and memory elements are provided in integrated circuits (ICs), which may be housed within mold structures and are generically called chips. Concurrently, there are commercial pressures to pack as many chips into as small a space as possible. The density of chips may lead to heat dissipation issues where heat can be trapped inside a small space, leading to heating of the chips. Excessive heating may damage the circuits inside the chips. Accordingly, some manufacturers desire the ability to verify that a chip is sufficiently rugged to withstand a wide range of operating temperatures and conditions. Finding a device that can perform these tests easily provides room for innovation.

### SUMMARY

Aspects disclosed in the detailed description include systems and methods for testing the thermal conditioning of an integrated circuit (IC). In particular, aspects of the present disclosure contemplate applying heat to a chip and, more particularly, to a memory element while providing thermal isolation to a motherboard with which circuits in the chip may be operating. Testing sensors may monitor the operation of the circuits in the chip while the heat is applied to the chip.

In a first aspect, the heating element may be provided in a riser card that lifts the chip under test (e.g., a memory element or memory module) away from the motherboard. In a second aspect, the heating element may be provided by a clamp that is selectively attached to the memory module. In a third aspect, the heating element may be a liquid-based heating element that operates in a tube similar to a liquid-cooled computing device, but instead of cooling fluid passing through the tube, heated fluid passes through the tube. In each case, having a device that is easily coupled to the memory module, readily applies heat without damaging other components on a motherboard, and allows testing of the memory module will save time and provide better test results so that chips may be certified for operation at such elevated temperatures and/or provide a better product to customers.

In this regard, in one aspect, a testing element is disclosed. The testing element includes a riser card comprising a heating element configured to be coupled to a power supply.

In another aspect, a testing element is disclosed. The testing element includes a tubular loop configured to receive a heated fluid; the tubular loop is further configured to be placed around a chip under test.

In another aspect, a method for testing a chip for thermal conditioning is disclosed. The method includes heating a chip under test that is in a socket in a riser card spaced from a motherboard, wherein the heating comprises using a heating element in the riser card. The method further includes measuring metrics associated with the chip under test.

### BRIEF DESCRIPTION OF THE DRAWINGS

FIG. 1 is a block diagram of an exemplary computing device;

FIG. 2 is a perspective view of a motherboard of a computing device with various elements mounted thereon;

FIG. 3A is a side elevation view of a memory module being tested with a clamp device according to a first aspect of the present disclosure;

FIG. 3B is a side elevation view of a memory module on a riser card being tested with a clamp device according to the first aspect of the present disclosure;

FIG. 3C is a perspective view of the riser card according to exemplary aspects of the present disclosure;

FIG. 4 is a schematic drawing of a memory module being tested with a riser card having heating elements therein;

FIG. 5 is a schematic drawing of a memory module being tested with a liquid heating element; and

FIG. 6 is a flowchart illustrating an exemplary process for testing an integrated circuit (IC) for thermal conditioning using one of the techniques set forth in FIGS. 3A-5.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that although the terms first, second, etc. may be used herein to describe various elements, these elements should not be limited by these terms. These terms are only used to distinguish one element from another. For example, a first element could be termed a second element, and similarly, a second element could be termed a first element without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element, or intervening elements may also be present. In contrast, when an element is referred to as being “directly on” or extending “directly onto” another element, no intervening elements are present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, no intervening elements are present. It will also be understood that when an element is referred to as being “connected” or “coupled” to another element, it can be directly connected or coupled to the other element, or intervening elements may be present. In contrast, when an element is referred to as being “directly connected” or “directly coupled” to another element, no intervening elements are present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Aspects disclosed in the detailed description include systems and methods for testing the thermal conditioning of an integrated circuit (IC). In particular, aspects of the present disclosure contemplate applying heat to a chip and, more particularly, to a memory element while providing thermal isolation to a motherboard with which circuits in the chip may be operating. Testing sensors may monitor the operation of the circuits in the chip while the heat is applied to the chip.

In a first aspect, the heating element may be provided in a riser card that lifts the chip under test (e.g., a memory module) away from the motherboard. In a second aspect, the heating element may be provided by a clamp that is selectively attached to the memory module. In a third aspect, the heating element may be a liquid-based heating element that operates in a tube similar to a liquid-cooled computing device, but instead of cooling fluid passing through the tube, heated fluid passes through the tube. In each case, having a device that is easily coupled to the memory module, readily applies heat without damaging other components on a motherboard, and allows testing of the memory module will save time and provide better test results so that chips may be certified for operation at such elevated temperatures and/or provide a better product to customers.

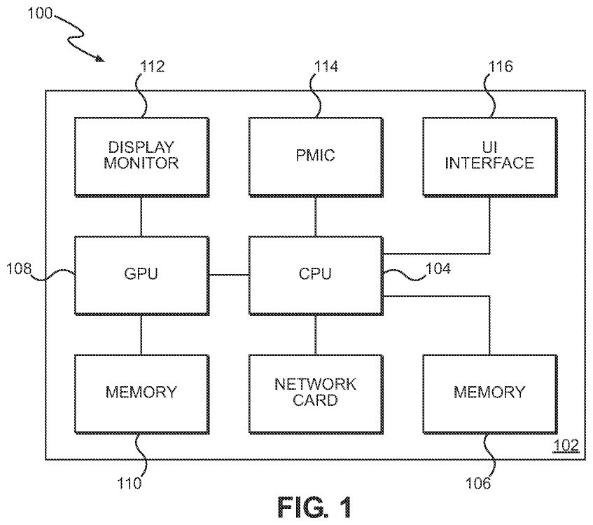

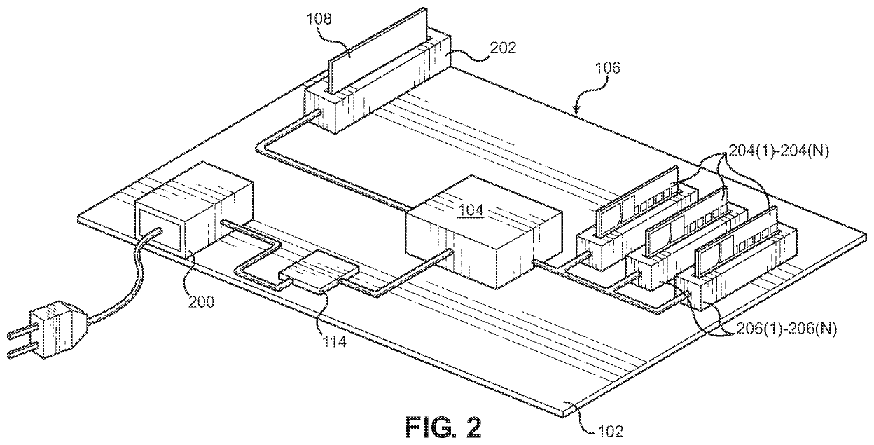

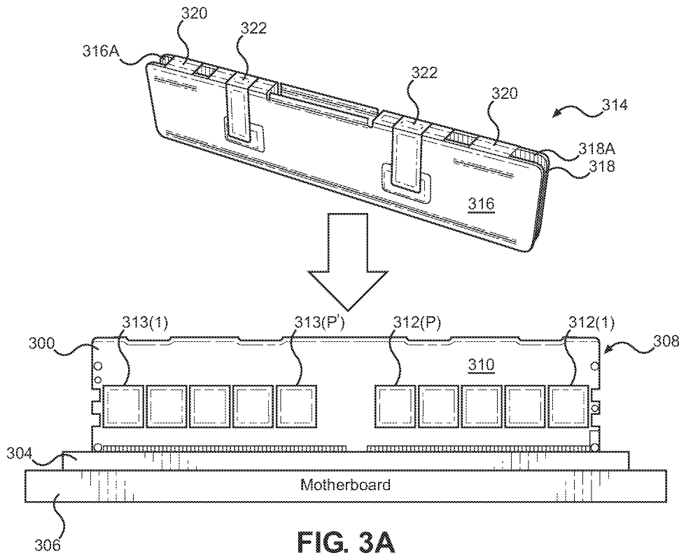

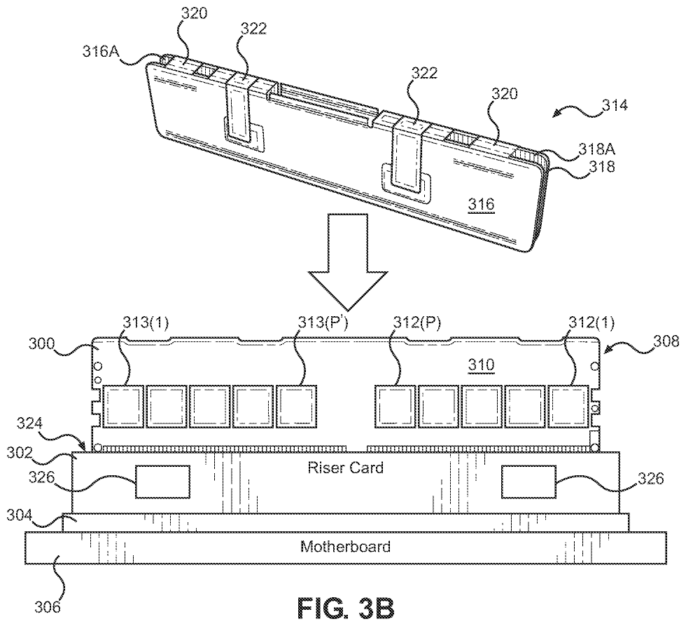

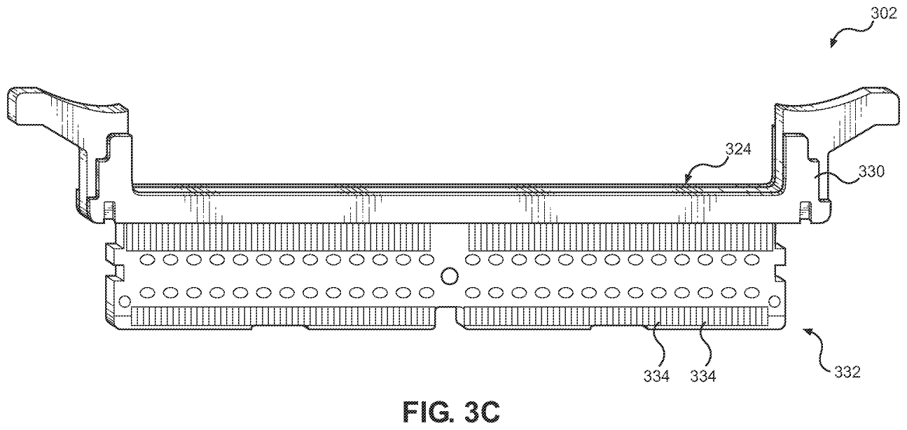

Before addressing aspects of the present disclosure, a brief overview of a computing device is provided with reference to FIGS. 1 and 2 so that the challenges associated with testing a chip for thermal conditioning can be better appreciated. A discussion of exemplary aspects begins below with reference to FIG. 3A-3C.

In this regard, FIG. 1 is a block diagram of a computing device 100 and, more particularly, a block diagram of some components or elements on a motherboard 102 of the computing device 100. The motherboard may be a printed circuit board (PCB) material with internal and/or surface-mounted wiring to interconnect elements, as is well understood. The heart (or perhaps brain depending on which metaphor the reader prefers) of the computing device 100 is the central processing unit (CPU) 104, which includes multiple cores, an internal clock, internal memory, and the ability to perform many thousands of operations per second. Additionally, the CPU 104 may be coupled to memory 106. Data may be stored in the memory 106 or read from the memory 106. Computer instructions that cause the CPU 104 to behave in certain manners may be stored in the memory and accessed as needed as is well understood. The CPU 104 may be coupled to a graphics processing unit (GPU) 108, which may have its own graphics memory 110 and be coupled to a display interface 112.

With continued reference to FIG. 1, the motherboard 102 may also have a power supply (not shown explicitly) and/or a power management IC (PMIC) 114 thereon. The CPU 104 may interoperate with a user interface (UI) interface circuit 116, which may allow functionality for a keyboard, mouse, or other user element as is well understood. Still other elements may be present without departing from the present disclosure.

FIG. 2 provides a perspective view of an exemplary motherboard 102 removed from a housing a computing device 100. The motherboard 102 may have the CPU 104 centrally located and coupled to the PMIC 114 to receive power from a power supply 200. The GPU 108 may be inserted into a socket 202. Likewise, memory 106 may be in the form of cards 204(1)-204(N) inserted into sockets 206(1)-206(N), respectively.

The sockets 206(1)-206(N) are generally relatively close together, meaning that the memory cards 204(1)-204(N) are also relatively close together. Getting a probe in these tight confines to test operation of the memory 106 is challenging. Making sure that the device is operating at a desired temperature in these tight confines while probing is a further challenge.

Aspects of the present disclosure assist in making sure that the chip under test, such as a memory chip or memory module positioned on a memory card, is at a desired temperature. While it is possible to test the memory module in situ, it may be easier to lift the memory card to provide easier access to the memory modules under test. Thus, a riser card may be used to elevate the chip under test. This riser card may be inserted into the socket of the chip on the motherboard using a known form factor having appropriate conductors (e.g., contact pads or fingers) to convey signals, power, and the like, and the riser card may also have a complementary socket into which the chip under test is inserted. This socket also has appropriate conductors to convey signals, power, and the like. Use of a riser card has the additional advantage of lifting the chip under test up and above the tight confines, such as may exist between sockets 206(1)-206(N).

FIG. 3A illustrates a memory module or, more generically, a chip under test 300 inserted directly into a socket 304 on a motherboard 306. The chip under test 300 may be, more accurately, a memory card 308 with a substrate 310 on which a plurality of memory chips 312(1)-312(P), 313(1)-313(P′) are mounted. Note that P may be equal to P′. A testing element 314 may be a clamp formed of a first slab 316 and a second slab 318. It should be appreciated that it is unlikely that there will be a one-size-fits-all clamp, so some of the details may be customized based on the chip under test 300. However, in general, the first slab 316 and the second slab 318 are generally elongated rectilinear shapes with heating elements 320 disposed on interior surfaces 316A, 318A, respectively. The heating elements 320 may be resistors that are designed to heat quickly when current is passed therethrough or Peltier devices with the hot sides facing inwardly and towards the chip under test 300. The testing element 314 clamps over the chip under test 300 such that the heating elements 320 are in contact with the memory chips 312(1)-312(P), 313(1)-313(P′). Spring elements 322 may keep the slabs 316, 318 in a pressure fit over the chip under test 300.

Temperature sensors may be in the testing element 314 (not shown). Such sensors provide feedback on a temperature such that an input current or voltage may be adjusted so that a desired temperature is applied to the chip under test 300. Probes (also not shown) may be used to measure metrics about the chip under test 300, as is well understood.

As noted, it may be difficult to access a memory module 204(1) inserted into a socket 206(1). Accordingly, a riser card 302, better illustrated in FIGS. 3B and 3C, may be used. The riser card 302 is inserted into the socket 304 using a known form factor having conductors (e.g., contact pads or contact fingers) arranged essentially identically to the conductors on the memory card 308. The chip under test 300 is, in turn, inserted into the socket 324 of the riser card 302. Temperature sensors 326 may be positioned within the riser card 302. Again, such sensors 326 provide feedback on a temperature such that an input current or voltage may be adjusted so that a desired temperature is applied to the chip under test 300.

FIG. 3C provides additional details about the riser card 302. In particular, the riser card 302 may be composed of several layers of circuit traces and material to form a body 330. One side has the socket 324 into which the memory module is inserted. The other side 332 is shaped into the known form factor having the contact pads or fingers 334 configured to plug into the socket 304. The internal circuit traces of the riser card 302 may also provide some incremental heat by running current therethrough. As an additional feature, use of the riser card 302 allows the heating to be done at a position removed from the motherboard 306.

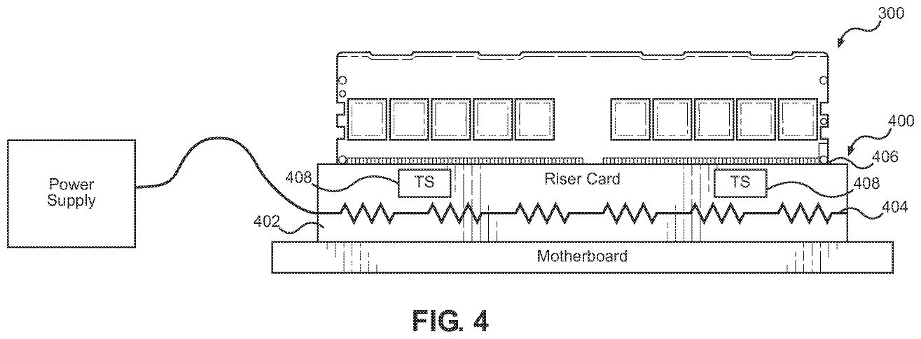

A second aspect is illustrated in FIG. 4, which takes advantage of the presence of the riser card. More specifically, FIG. 4 illustrates testing element 400 in riser card 402. The testing element includes heating elements 404. As illustrated, the heating elements 404 are resistors (as opposed to general internal traces discussed above) that generate heat that travels through the contacts and substrate material of the chip under test 300 that are inserted into the socket 406 of the riser card 402. While resistors are shown, it should be appreciated that the heating elements 404 may be Peltier devices. Temperature sensors 408 may be used to provide feedback about a temperature generated so that a desired temperature may be selected. A probe (not shown) may measure metrics for the chip under test.

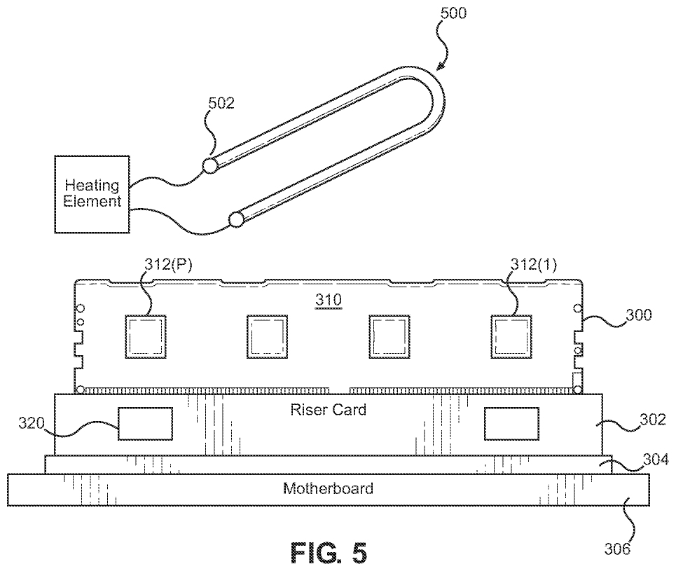

A third aspect is illustrated in FIG. 5. The chip under test 300 and its mounting elements are identical to those described above with respect to FIG. 3A-3C. However, a testing element 500 is a flexible plastic tube 502 through which a fluid (e.g., an alcohol mix, water, or the like) may pass. The fluid is heated in a heating reservoir 504 and pumped through the tube 502. In an exemplary aspect, this tube 502 and the fluid therein are identical to that used by water-cooled computing devices. However, instead of cooling the chip under test 300, the heated fluid within the tube 502 heats the chip under test.

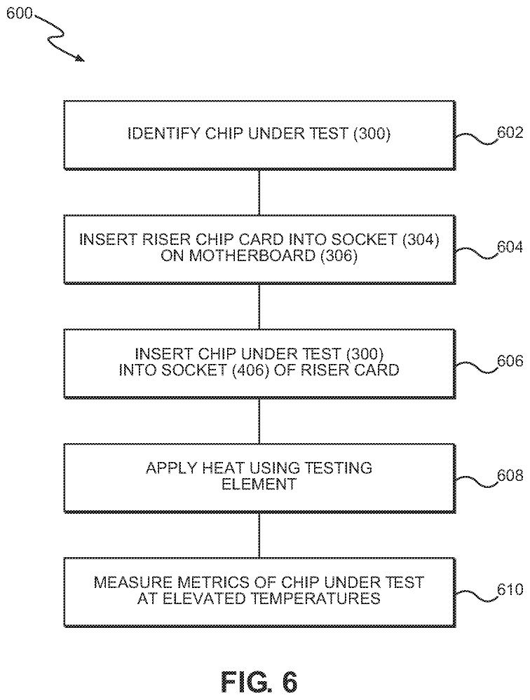

A method of using the different aspects of the present disclosure is provided with reference to process 600 in FIG. 6. Initially, the tester identifies the chip under test 300 (block 602). In particularly contemplated aspects, the chip under test 300 is a memory stick but can be otherwise without departing from the present disclosure. The tester inserts a riser card into the socket 304 on the motherboard 306 (block 604). The chip under test 300 is then inserted into the socket 406 of the riser card (block 606). Heat is applied to the chip under test 300 by the heating element (block 608), and metrics associated with the chip under test 300 are measured at the elevated temperatures (block 610).

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications, as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein but is to be accorded the widest scope consistent with the principles and novel features disclosed herein.

What is claimed is:

1. A testing element, comprising:
a riser card comprising a heating element configured to be coupled to a power supply.

2. The testing element of claim 1, further comprising a socket configured to receive a chip under test.

3. The testing element of claim 1, further comprising a temperature sensor configured to report a temperature to a remote location.

4. The testing element of claim 1, further comprising an insertion blade configured to be inserted into a motherboard.

5. The testing element of claim 1, wherein the heating element comprises a resistor.

6. The testing element of claim 1, wherein the heating element comprises a Peltier device.

7. The testing element of claim 1, wherein the heating element comprises an internal trace conductor.

8. A testing element comprising:
a tubular loop configured to receive a heated fluid, the tubular loop further configured to be placed around a chip under test.

9. A method for testing a chip for thermal conditioning, comprising:
heating a chip under test that is in a socket in a riser card spaced from a motherboard, wherein the heating comprises using a heating element in the riser card; and
measuring metrics associated with the chip under test.

10. The method of claim 9, further comprising placing the riser card into a second socket on the motherboard.

11. The method of claim 10, further comprising placing the chip under test into the socket in the riser card.

12. The method of claim 9, wherein heating the chip under test comprises heating a memory module.

13. The method of claim 9, wherein heating the chip under test comprises using resistors in the riser card to heat the chip under test.

14. The method of claim 9, wherein heating the chip under test comprises using a Peltier device in the riser card.

15. The method of claim 9, further comprising sensing a temperature in the riser card with a temperature sensor.
